(19) United States
(12) Patent Application Publication
(10) Pub. No.: US 2024/0263308 A1
(43) Pub. Date: Aug. 8, 2024

(54) SUBSTRATE TREATMENT APPARATUS AND SUBSTRATE TREATMENT METHOD USING THE SAME

(71) Applicant: HANWHA PRECISION MACHINERY CO., LTD., Changwon-si (KR)

(72) Inventors: Dong Won SEO, Changwon-si (KR); Dong Suk KANG, Changwon-si (KR); Yoo Seong KIM, Changwon-si (KR); Jeong Sub SHIN, Changwon-si (KR); Kyu Beom LEE, Changwon-si (KR)

(73) Assignee: HANWHA PRECISION MACHINERY CO., LTD., Changwon-si (KR)

(21) Appl. No.: 18/640,875

(22) Filed: Apr. 19, 2024

Related U.S. Application Data
(63) Continuation of application No. PCT/KR2022/006540, filed on May 9, 2022.

(30) Foreign Application Priority Data
Oct. 19, 2021 (KR) 10-2021-0138904

(51) Int. Cl. C23C 16/455; C23C 16/44; H01L 21/02; H01L 21/67

(52) U.S. Cl. CPC C23C 16/45536; C23C 16/4412; C23C 16/45557; H01L 21/02697; H01L 21/67201

(57) ABSTRACT

A substrate treatment apparatus including a process chamber configured to process a wafer therein; a load lock chamber configured to accommodate the wafer and configured to switch between an atmospheric state and a vacuum state; and a load lock radical supply configured to supply radicals into the load lock chamber. The substrate treatment apparatus further including: a front opening unified pod (FOUP) configured to accommodate the wafer; an equipment front end module (EFEM) provided between the FOUP and the load lock chamber, the EFEM configured to transfer the wafer to the load lock chamber in the atmospheric state; and a transfer chamber provided between the process chamber and the load lock chamber, the transfer chamber configured to transfer the wafer to the process chamber in the vacuum state

### CROSS-REFERENCE TO RELATED APPLICATION(S)

This application is a continuation of International Application No. PCT/KR2022/006540, filed on May 9, 2022, in the Korean Intellectual Property Receiving Office, which is based on and claims priority to Korean Patent Application No. 10-2021-0138904, filed on Oct. 19, 2021, in the Korean Intellectual Property Office, the disclosures of which are incorporated by reference herein in their entireties.

### BACKGROUND

### 1. Field

This disclosure relates to a substrate treatment apparatus and a substrate treatment method using the same, and more particularly, to a substrate treatment apparatus capable of performing thin film surface treatment by supplying radicals into a load lock for transferring a substrate to a process module, and substrate treatment method using the same.

### 2. Description of Related Art

Generally, in a semiconductor manufacturing facility, a substrate treatment apparatus may include a process chamber in which a process is performed in a vacuum state, and other chambers installed adjacent to the process chamber.

That is, the substrate treatment apparatus may include a Front Opening Unified Pod (FOUP) for storing wafers, a process chamber in which a processing process of the substrate is performed, a load lock chamber that loads or unloads the wafers for processing and is switched between atmospheric and vacuum states, an Equipment Front End Module (EFEM) positioned between the FOUP and the load lock chamber to transfer the wafers in the atmospheric state, and a transfer chamber installed between the process chamber and the load lock chamber to transfer the wafers in the vacuum state.

When the substrate treatment apparatus performs a low-temperature atomic layer deposition of titanium nitride (ALD TiN) process, electrical characteristics of the wafer may deteriorate due to a Cl component present in a thin film. To solve such a problem, the substrate treatment apparatus has been developed to continuously increase a process temperature.

However, in the substrate treatment apparatus, temperature restrictions may occur due to an influence of a base film, and a method of performing plasma treatment within the process chamber was applied to improve the electrical characteristics of the ALD TiN thin film.

This had the problem of lengthening the process time, reducing productivity and complicating the process.

### SUMMARY

Provided is a substrate treatment apparatus capable of performing thin film surface treatment by supplying radicals into a load lock chamber and a substrate treatment method using the same.

Additional aspects will be set forth in part in the description which follows and, in part, will be apparent from the description, or may be learned by practice of the presented embodiments.

According to an aspect of the disclosure, a substrate treatment apparatus may include: a process chamber configured to process a wafer therein; a load lock chamber configured to accommodate the wafer and configured to switch between an atmospheric state and a vacuum state; and a load lock radical supply configured to supply radicals into the load lock chamber.

The substrate treatment apparatus may further include: a front opening unified pod (FOUP) configured to accommodate the wafer; an equipment front end module (EFEM) provided between the FOUP and the load lock chamber, the EFEM configured to transfer the wafer to the load lock chamber in the atmospheric state; and a transfer chamber provided between the process chamber and the load lock chamber, the transfer chamber configured to transfer the wafer to the process chamber in the vacuum state.

The load lock radical supply may include: a radical generator configured to generate the radicals from a gas including hydrogen; and a radical supply line configured to supply the radicals from the radical generator to the load lock chamber.

The radical generator may include at least one of a remote plasma generator, a microwave plasma device, or a direct plasma device.

The load lock radical supply may further include a radical supply amount control valve provided in the radical supply line and configured to open and close a flow path of the radical supply line.

The load lock radical supply may further include a pump provided on the radical supply line.

The load lock radical supply may be further configured to remove a Cl component in a film generated on a surface of the wafer based on supplying the radicals into the load lock chamber.

The process chamber may include: a first gas supply configured to supply a first reactant gas of TiCl₄ into the process chamber; and a second gas supply configured to supply a second reactant gas of NH₃ into the process chamber and deposit a TiN film on the wafer through an atomic layer deposition (ALD) method.

When the wafer is transferred into the load lock chamber from the FOUP, the load lock radical supply may supply the radicals into the load lock chamber.

The load lock chamber may include: a first wafer support configured to accommodate a first wafer before the process in the process chamber; and a second wafer support configured to accommodate a second wafer after the process in the process chamber, where, in a state in which the first wafer and the second wafer are accommodated on the first wafer support and the second wafer support respectively, the load lock radical supply is configured to supply the radicals into the load lock chamber.

According to an aspect of the disclosure, a substrate treating method may include: transferring a wafer from a load lock chamber into a process chamber; depositing a film on the wafer; transferring the wafer on which the film is deposited to the load lock chamber after depositing the film on the wafer; and supplying radicals into the load lock chamber after the wafer is transferred into the load lock chamber.

The supplying the radicals into the load lock chamber may include an exhaust process and a cooling process based on supplying a radical gas or a mixed gas of radicals and nitrogen into the load lock chamber.

The supplying the radicals into the load lock chamber may include removing a Cl component in the film.

The depositing the film on the wafer may include depositing a TiN film on the wafer through an atomic layer deposition (ALD) method.

The method may further include: transferring a first wafer from a front opening unified pod (FOUP) into the load lock chamber; and supplying the radicals into the load lock chamber before transferring the first wafer from the load lock chamber into the process chamber.

The supplying the radicals into the load lock chamber before the transferring the first wafer from the load lock chamber into the process chamber may include removing oxygen from a surface of the first wafer or oxidizing the surface of the first wafer.

The method may further include, based on the transferring the first wafer from the FOUP into the load lock chamber, and the transferring the wafer on which the film is deposited into the load lock chamber, supplying the radicals into the load lock chamber.

The depositing the film on the wafer may include: supplying a first reactant gas of TiCl₄ into the process chamber; supplying a second reactant gas of NH₃ into the process chamber; and depositing a TiN film on the wafer through an Atomic Layer Deposition (ALD) method.

The supplying the radicals into the load lock chamber may include: generating radicals with a gas including hydrogen; and supplying the radicals into the load lock chamber.

The generating the radicals may include using at least one of a remote plasma generator, a microwave plasma device, or a direct plasma device.

According to an aspect of the disclosure, a substrate treatment apparatus may include: a process chamber configured to process a wafer therein; a load lock chamber configured to accommodate a first wafer and a second wafer, and configured to switch between an atmospheric state and a vacuum state; a transfer chamber provided between the process chamber and the load lock chamber, the transfer chamber configured to transfer the first wafer to the process chamber in the vacuum state; a load lock radical supply configured to supply radicals into the load lock chamber; and a controller configured to: control the transfer chamber to transfer the first wafer from the load lock chamber into the process chamber, control the process chamber to process the first wafer, and control the load lock radical supply to supply radicals into the load lock chamber.

The substrate treatment apparatus may further include: a front opening unified pod (FOUP) configured to accommodate the wafer; and an equipment front end module (EFEM) provided between the FOUP and the load lock chamber, the EFEM configured to transfer the wafer to the load lock chamber in the atmospheric state, where the controller is further configured to: control the EFEM to transfer the second wafer from the FOUP into the load lock chamber, control the transfer chamber to transfer the first wafer from the process chamber into the load lock chamber, and in a state in which the first wafer and the second wafer are accommodated in the load lock chamber, control the load lock radical supply to supply radicals into the load lock chamber.

The process chamber may include: a first gas supply configured to supply a first reactant gas of TiCl₄ into the process chamber; and a second gas supply configured to supply a second reactant gas of NH₃ into the process chamber and deposit a TiN film on the wafer through an atomic layer deposition (ALD) method, where the load lock radical supply may include: a radical generator configured to generate radicals from a gas including hydrogen; a radical supply line configured to supply the radicals from the radical generator to the load lock chamber; and a radical supply amount control valve provided in the radical supply line and configured to open and close a flow path of the radical supply line.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a schematic diagram illustrating an embodiment of a substrate treatment apparatus according to an embodiment;

FIG. 2 is a flowchart illustrating an embodiment of a substrate treatment method according to an embodiment; and

FIG. 3 is a schematic diagram illustrating a state in which Cl components are removed through radical supply within a load lock chamber in the substrate treatment apparatus and substrate treatment method according to an embodiment.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

It will be understood that when the terms “containing,” “contains,” “includes,” “comprises,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

The term “or” includes any and all combinations of one or more of a plurality of associated listed items.

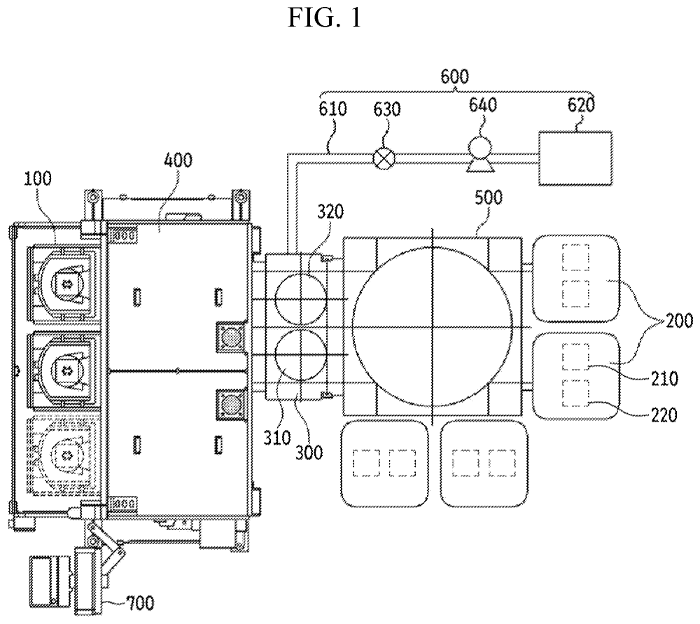

FIG. 1 is a schematic diagram illustrating an embodiment of a substrate treatment apparatus according to the present disclosure, and an embodiment of a substrate treatment apparatus according to the present disclosure will be described in detail below with reference to FIG. 1.

Referring to FIG. 1, an embodiment of a substrate treatment apparatus according to the present disclosure may include a process chamber 200 in which a processing process of a wafer is performed, a load lock chamber 300 in which a wafer transferred into the process chamber 200 is loaded and switched between an atmospheric state and a vacuum state, and a load lock radical supply 600 that supplies radicals into the load lock chamber 300.

In addition, an embodiment of a substrate treatment apparatus according to the present disclosure may further include a Front Opening Unified Pod (FOUP) 100 for storing the wafers loaded into the load lock chamber 300, an Equipment Front End Module (EFEM) 400 positioned between the FOUP 100 and the load lock chamber 300 to transfer the wafers to the load lock chamber 300 in the atmospheric state, and a transfer chamber 500 installed between the process chamber 200 and the load lock chamber 300 to transfer the wafers to the process chamber 200 in the vacuum state.

As an example, the process chamber 200 will be described as a deposition chamber that deposits a metal thin film on the wafer loaded therein.

The process chamber 200 may include a susceptor in which a substrate is seated, a shower head that sprays a reactant gas onto the susceptor, and a reactant gas supply that supplies the reactant gas thereinto.

As an example, in the substrate treatment apparatus, the process chamber 200 may include a first gas supply that supplies a first reactant gas of TiCl₄ into the chamber and a second gas supply that supplies a second reactant gas of NH₃ into the chamber to deposit a TiN thin film on the wafer using the Atomic Layer Deposition (ALD) method.

The load lock chamber 300 may be positioned between the EFEM 400 and the transfer chamber 500, and may receive the wafer stored in the FOUP 100 from the EFEM 400 in the atmospheric state. The load lock chamber 300 may transfer the wafer to the process chamber 200 through the transfer chamber 500 in the vacuum state.

The EFEM 400 may use a local cleaning system to minimize foreign contamination during wafer transfer. The EFEM 400 may be known in the art, such as including a load port, an ATM robot, and an aligner, and the like, thus further detailed description will be omitted.

The EFEM 400 may automatically perform loading and unloading of the wafers, and may transfer the wafers stored in the FOUP 100 into the load lock chamber 300 in a cleaning system using a HEPA filter.

The EFEM 400 may load the wafer into the load lock chamber 300 or unload the wafer within the load lock chamber 300 to transfer the wafer back into the FOUP 100.

The wafer loaded into the load lock chamber 300 may be transferred into the process chamber 200 through the transfer chamber 500.

The transfer chamber 500 may be connected to a vacuum pump to maintain an interior thereof in a vacuum state, and may transfer the wafer loaded in the load lock chamber 300 into the process chamber 200 in the vacuum state.

The transfer chamber 500 may include a transfer robot therein to transfer the wafer in the load lock chamber 300 into the process chamber 200 in the vacuum state.

The transfer chamber 500 may be implemented with various modifications to the known structure that may include the transfer robot being configured to transfer the wafer from the load lock chamber 300 to the process chamber 200 in the vacuum, or transfer the wafer from the process chamber 200 to the load lock chamber 300.

The load lock chamber 300 may receive the wafer in the atmospheric state when the wafer is transferred into the load lock chamber 300 through the EFEM 400, and may switch to the vacuum state when transferring the wafer into the process chamber 200, such that the wafer may be transferred into the process chamber 200 through the transfer chamber 500 in the vacuum state.

The load lock chamber 300 may be connected to the vacuum pump to switch an internal state of the load lock chamber 300 to the atmospheric state and the vacuum state.

The load lock chamber 300 may be maintained in the atmospheric state when receiving the wafer of FOUP 100 with the EFEM 400, or when transferring the processed wafer back to the inside of the FOUP 100 from the EFEM 400. The load lock chamber 300 may switch into the vacuum state when transferring the wafer into the process chamber 200 with the transfer robot within the transfer chamber 500 or, when receiving the wafer processed in the process chamber 200 with the transfer robot within the transfer chamber 500.

The load lock chamber 300 may include two wafer supports, such that a wafer before process treatment may be seated through one wafer support and a wafer after process treatment may be seated through another wafer support.

An embodiment of the substrate treatment apparatus according to the present disclosure may include a load lock radical supply 600 that supplies radicals into the load lock chamber 300.

The load lock radical supply 600 may supply hydrogen radicals.

The load lock radical supply 600 may include a radical supply line 610 that supplies radicals into the load lock chamber 300 and a radical generator 620 that generates the radicals supplied through the radical supply line 610 using a gas containing hydrogen.

The radical generator 620 may include at least one of a remote plasma generator, a microwave plasma device, and a direct plasma device. For instance, the radical generator 620 may generate the radicals from the gas containing hydrogen using any one or more of a remote plasma generator, a microwave plasma device, and a direct plasma device. A remote plasma device may include a device that produces plasma in a location that is physically separate from the substrate processing area. A microwave plasma device may include a device that generates plasma by applying microwave energy to a gaseous medium. A direct plasma device generates plasma within or near the substrate processing area.

Examples of the gas containing hydrogen may include hydrogen gas and ammonia gas, and it should be noted that the present disclosure may be carried out in various ways with known gases that may generate radicals.

The remote plasma generator and the microwave plasma device may generate plasma to generate radicals, and may supply the generated radicals into the load lock chamber 300 through the radical supply line 610, thereby minimally changing a structure of the load lock chamber 300.

The direct plasma device directly may generate radicals by supplying hydrogen and discharging plasma.

In addition, the load lock radical supply 600 may further include a radical supply amount control valve 630 positioned in the radical supply line 610 to open and close a flow path of the radical supply line 610.

In addition, the load lock radical supply 600 may further include a pump 640 mounted on the radical supply line 610.

The load lock radical supply 600 may adjust a supply pressure of radicals by controlling the operation of the radical supply amount control valve 630 and the pump 640, thereby adjusting a supply amount of radicals.

The load lock radical supply 600 may generate hydrogen radicals using any one or more of the radical generator 620, that is, a remote plasma generator, a microwave plasma device, and a direct plasma device, and supplying the generated hydrogen radicals into the load lock chamber 300 through the radical supply line 610.

The load lock radical supply 600 may improve a thin film quality of the wafer through surface treatment of the wafer positioned in the load lock chamber 300 by supplying the radicals into the load lock chamber 300, and may increase productivity by simplifying a separate surface treatment process after the process performed in the process chamber 200.

When the wafer on which the thin film of the wafer is treated, that is, the wafer on which the thin film is generated in the process chamber 200 is transferred into the load lock chamber 300 to be transported into the FOUP 100, the load lock radical supply 600 may supply radicals into the load lock chamber 300 to remove Cl components in the film formed on the surface. This in turn may improve a quality of the film.

In addition, before the wafer is loaded into the process chamber 200, that is, when the wafer is loaded into the load lock chamber 300 from the FOUP 100, the load lock radical supply 600 may supply radicals into the load lock chamber 300 and may treat the surface of the wafer before the process treatment performed in the process chamber 200. Thus, the load lock radical supply 600 may improve the interface characteristics of the wafer by performing surface oxidation treatment or removing oxygen.

The load lock chamber 300 may include a first wafer support 310 on which a wafer before process treatment is seated and a second wafer support 320 on which a wafer after process treatment is seated. The load lock chamber 300 may simultaneously perform surface treatment of removing Cl components from the surface of the process treated wafer, and surface treatment that improves interface characteristics by removing oxygen or oxidizing the surface of the wafer before the process treatment, while supplying radicals into the load lock chamber 300 through the load lock radical supply 600 in a state in which the wafer before the process treatment is seated on the first wafer support 310 and the wafer after the process treatment is seated on the second wafer support 320.

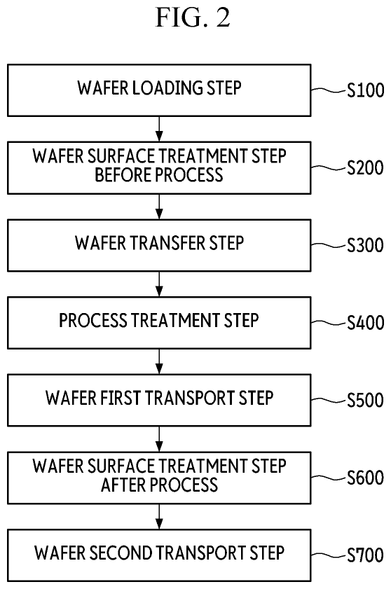

FIG. 2 is a flowchart illustrating a substrate treatment method according to an embodiment of the present disclosure. An embodiment of the substrate treatment method according to the present disclosure will be described in detail below with reference to FIGS. 1 and 2.

An embodiment of the substrate treatment method according to the present disclosure may include a wafer transfer step (S300) of transferring a wafer from a load lock chamber 300 into a process chamber 200, a process treatment step (S400) of depositing and generating a thin film on the loaded wafer, a first wafer transport step (S500) of transferring the wafer on which the thin film is deposited to the load lock chamber 300 after the process treatment step (S400), and a wafer surface treatment step (S600) after the process of treating a surface of the wafer by supplying radicals into the load lock chamber 300 after the wafer is transferred into the load lock chamber 300 in the first wafer transport step (S500).

The wafer transfer step (S300) and the first wafer transport step (S500) are performed in a vacuum state by a transfer chamber 500 positioned between the load lock chamber 300 and the process chamber 200, and a transfer robot capable of transferring the wafer between the load lock chamber 300 and the process chamber 200 is positioned inside the transfer chamber 500.

As previously mentioned, the transfer chamber 500 including the transfer robot may be implemented in various modifications to a known transfer module TM structure in a semiconductor manufacturing facility, and thus further detailed description will be omitted.

The substrate treatment method according to the present disclosure may further include a wafer loading step (S100) of loading a wafer in a FOUP 100 into the load lock chamber 300 using an EFEM 400.

The substrate treatment method according to the present disclosure may further include a second wafer transfer step (S700) of unloading the wafer in the load lock chamber 300 into the FOUP 100 using the EFEM 400 after the wafer surface treatment step.

It should be noted that the EFEM 400 may be implemented with various modifications to a known structure in a semiconductor manufacturing facility, and thus more detailed description will be omitted.

As an example, in the process treatment step (S400), a TiN thin film may be deposited on the wafer using an Atomic Layer Deposition (ALD) method.

In addition, as an example, in the wafer surface treatment step, surface treatment of removing Cl components remaining in the thin film by supplying radicals into the load lock chamber 300 may be performed.

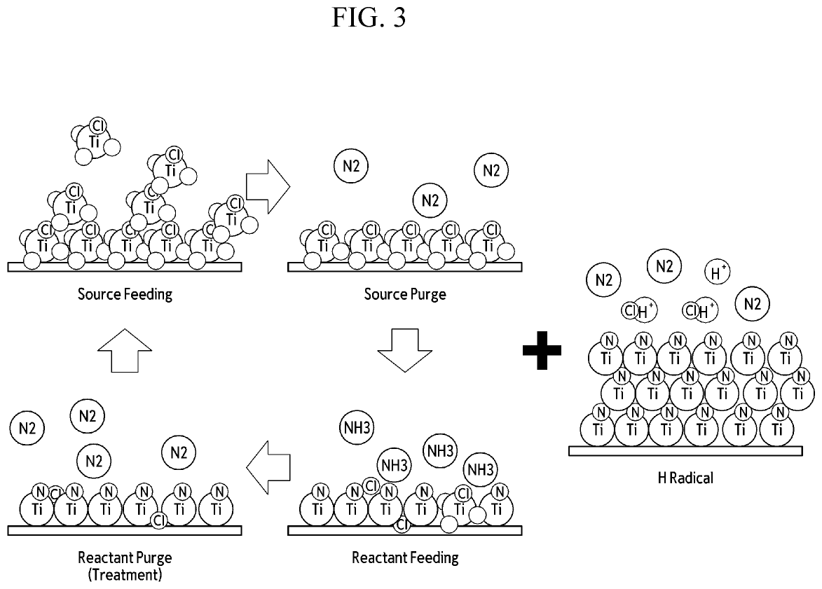

FIG. 3 is a schematic diagram illustrating a state in which Cl components are removed through radical supply within a load lock chamber 300 in the substrate treatment apparatus and substrate treatment method according to the present disclosure. Referring to FIG. 3, when radicals are supplied into the load lock chamber 300, the Cl component of the thin film may be removed according to the following reaction formula:

$${TiCl}_{4} + {NH}_{3} \to TiN ( s ) + HCl ( g ) \qquad [ TiN Process Reaction Formula ]$$

In the wafer surface treatment step (S600), the surface of the wafer may be treated using radicals, by supplying a radical gas or a mixed gas of radicals and nitrogen into the load lock chamber 300 after the wafer first transport step (S500) to perform an exhaust process to atmospheric pressure and a cooling process.

That is, in the wafer surface treatment step (S600), through the Atomic Layer Deposition (ALD) method, the Cl component, which is an impurity, may be removed from the thin film of the wafer on which the TiN thin film is generated, which may improve the film quality and improve a density of the deposited film.

In addition, in the surface treatment step (S600), by supplying the radicals into the load lock chamber 300 during the transfer process for process treatment of wafer, productivity may be improved without increasing a process time due to a separate surface treatment process.

The substrate treatment method according to the present disclosure may further include a wafer surface treatment step (S200) before a process of treating the surface of the wafer by supplying the radicals into the load lock chamber 300, after the wafer loading step (S100) and before the wafer transfer step (S300).

In the wafer surface treatment step (S200) before the process, the interface characteristics of the wafer may be improved by oxidizing the surface of the wafer or removing oxygen by supplying the radicals into the load lock chamber 300 before thin film deposition on the wafer.

The wafer surface treatment step (S200) before the process and the wafer surface treatment step (S600) after the process may also be simultaneously performed in the load lock chamber 300.

A wafer to be newly transferred into the process chamber 200 may be seated inside the load lock chamber 300, and the wafer on which the thin film is deposited within the process chamber 200 may wait to be transferred back to the inside of the FOUP 100.

In the wafer surface treatment step (S200) before the process and the wafer surface treatment step (S600) after the process, by supplying the radicals into the load lock chamber 300 in a state in which the wafer to be newly transferred into the process chamber 200 is transferred into the load lock chamber 300, and the wafer on which the thin film is deposited within the process chamber 200 is transferred into the load lock chamber 300, the interface characteristics of the wafer before process treatment (e.g., before thin film deposition) may be improved. Simultaneously, the film quality may be improved by removing Cl components in the thin film from the wafer after process treatment, (e.g., after thin film deposition).

The substrate treatment apparatus may further include a controller configured to execute the above-described steps. The controller may be physically implemented by analog and/or digital circuits including one or more of a logic gate, an integrated circuit, a microprocessor, a system-on-chip (SoC), a microcontroller, a memory circuit, a passive electronic component, an active electronic component, an optical component, and the like, and may implement or execute software and/or firmware to perform the functions or operations described herein.

The controller 700 may control the various components to perform the steps, methods, and operations described herein. For example, the controller 700 may control the loading and unloading of a wafer into and out of the FOUP 100. The controller 700 may control the EFEM 400 to transfer the wafer from the FOUP 100 to the load lock chamber 300, and may control the EFEM 400 to transfer the wafer from the load lock chamber 300 to the FOUP 100. The controller 700 may control the transfer chamber 500 to transfer a wafer from the load lock chamber 300 to the process chamber 200, and may control the transfer chamber 500 to transfer a wafer from the process chamber 200 to the load lock chamber. The controller may set the state of the load lock chamber 300 in either the vacuum state or the atmospheric state. The controller 700 may control the supply of radicals from the load lock radical supply 600 via the radical supply amount control valve 630. The following are merely examples, and the controller may be configured to control the various components described herein to perform the respective operations.

According to the present disclosure, since the thin film surface treatment may be performed by supplying the radicals to the load lock chamber 300 when unloading the wafer within the load lock chamber 300, the process time may be shortened and the productivity may be increased.

According to the present disclosure, the interface characteristics may be improved by treating the surface of the wafer before a process of the wafer, that is, before deposition of the wafer, by supplying hydrogen radicals when loading the substrate within the load lock chamber 300, and surface oxidation treatment or oxygen removal is possible to improve the quality of the deposition process of the substrate.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. A substrate treatment apparatus comprising:
a process chamber configured to process a wafer therein;
a load lock chamber configured to accommodate the wafer and configured to switch between an atmospheric state and a vacuum state; and
a load lock radical supply configured to supply radicals into the load lock chamber.

2. The substrate treatment apparatus of claim 1, further comprising:
a front opening unified pod (FOUP) configured to accommodate the wafer;
an equipment front end module (EFEM) provided between the FOUP and the load lock chamber, the EFEM configured to transfer the wafer to the load lock chamber in the atmospheric state; and
a transfer chamber provided between the process chamber and the load lock chamber, the transfer chamber configured to transfer the wafer to the process chamber in the vacuum state.

3. The substrate treatment apparatus of claim 1, wherein the load lock radical supply comprises:
a radical generator configured to generate the radicals from a gas including hydrogen; and
a radical supply line configured to supply the radicals from the radical generator to the load lock chamber.

4. The substrate treatment apparatus of claim 3, wherein the radical generator comprises at least one of a remote plasma generator, a microwave plasma device, or a direct plasma device.

5. The substrate treatment apparatus of claim 3, wherein the load lock radical supply further comprises a radical supply amount control valve provided in the radical supply line and configured to open and close a flow path of the radical supply line.

6. The substrate treatment apparatus of claim 5, wherein the load lock radical supply further comprises a pump provided on the radical supply line.

7. The substrate treatment apparatus of claim 1, wherein the load lock radical supply is further configured to remove a Cl component in a film generated on a surface of the wafer based on supplying the radicals into the load lock chamber.

8. The substrate treatment apparatus of claim 7, wherein the process chamber comprises:
a first gas supply configured to supply a first reactant gas of TiCl₄ into the process chamber; and
a second gas supply configured to supply a second reactant gas of NH₃ into the process chamber and deposit a TiN film on the wafer through an atomic layer deposition (ALD) method.

9. The substrate treatment apparatus of claim 2, wherein, when the wafer is transferred into the load lock chamber from the FOUP, the load lock radical supply is configured to supply the radicals into the load lock chamber.

10. The substrate treatment apparatus of claim 9, wherein the load lock chamber comprises:
a first wafer support configured to accommodate a first wafer before the process in the process chamber; and
a second wafer support configured to accommodate a second wafer after the process in the process chamber,
wherein in a state in which the first wafer and the second wafer are accommodated on the first wafer support and the second wafer support respectively, the load lock radical supply is configured to supply the radicals into the load lock chamber.

11. A substrate treatment method comprising:
transferring a wafer from a load lock chamber into a process chamber;
depositing a film on the wafer;
transferring the wafer on which the film is deposited to the load lock chamber after depositing the film on the wafer; and
supplying radicals into the load lock chamber after the wafer is transferred into the load lock chamber.

12. The substrate treatment method of claim 11, wherein the supplying the radicals into the load lock chamber comprises an exhaust process and a cooling process based on supplying a radical gas or a mixed gas of radicals and nitrogen into the load lock chamber.

13. The substrate treatment method of claim 11, wherein the supplying the radicals into the load lock chamber comprises removing a Cl component in the film.

14. The substrate treatment method of claim 13, wherein the depositing the film on the wafer comprises depositing a TiN film on the wafer through an atomic layer deposition (ALD) method.

15. The substrate treatment method of claim 11, further comprising:
transferring a first wafer from a front opening unified pod (FOUP) into the load lock chamber; and
supplying the radicals into the load lock chamber before transferring the first wafer from the load lock chamber into the process chamber.

16. The substrate treatment method of claim 15, wherein the supplying the radicals into the load lock chamber before the transferring the first wafer from the load lock chamber into the process chamber comprises removing oxygen from a surface of the first wafer or oxidizing the surface of the first wafer.

17. The substrate treatment method of claim 16, further comprising, based on the transferring the first wafer from the FOUP into the load lock chamber, and the transferring the wafer on which the film is deposited into the load lock chamber, supplying the radicals into the load lock chamber.

18. The substrate treatment method of claim 11, wherein the depositing the film on the wafer comprises:
supplying a first reactant gas of TiCl₄ into the process chamber;
supplying a second reactant gas of NH₃ into the process chamber; and
depositing a TiN film on the wafer through an atomic layer deposition (ALD) method.

19. The substrate treatment method of claim 11, wherein the supplying the radicals into the load lock chamber comprises:
generating radicals with a gas including hydrogen; and
supplying the radicals into the load lock chamber.

20. The substrate treatment method of claim 11, wherein the generating the radicals comprises using at least one of a remote plasma generator, a microwave plasma device, or a direct plasma device.

21. A substrate treatment apparatus comprising:
a process chamber configured to process a wafer therein;
a load lock chamber configured to accommodate a first wafer and a second wafer, and configured to switch between an atmospheric state and a vacuum state;
a transfer chamber provided between the process chamber and the load lock chamber, the transfer chamber configured to transfer the first wafer to the process chamber in the vacuum state;
a load lock radical supply configured to supply radicals into the load lock chamber; and
a controller configured to:
control the transfer chamber to transfer the first wafer from the load lock chamber into the process chamber,
control the process chamber to process the first wafer, and
control the load lock radical supply to supply radicals into the load lock chamber.

22. The substrate treatment apparatus of claim 21, further comprising:
a front opening unified pod (FOUP) configured to accommodate the wafer; and
an equipment front end module (EFEM) provided between the FOUP and the load lock chamber, the EFEM configured to transfer the wafer to the load lock chamber in the atmospheric state,
wherein the controller is further configured to:
control the EFEM to transfer the second wafer from the FOUP into the load lock chamber,
control the transfer chamber to transfer the first wafer from the process chamber into the load lock chamber, and
in a state in which the first wafer and the second wafer are accommodated in the load lock chamber, control the load lock radical supply to supply radicals into the load lock chamber.

23. The substrate treatment apparatus of claim 22, wherein the process chamber comprises:
a first gas supply configured to supply a first reactant gas of TiCl₄ into the process chamber; and
a second gas supply configured to supply a second reactant gas of NH₃ into the process chamber and deposit a TiN film on the wafer through an atomic layer deposition (ALD) method, and
wherein the load lock radical supply comprises:
a radical generator configured to generate radicals from a gas including hydrogen;
a radical supply line configured to supply the radicals from the radical generator to the load lock chamber; and
a radical supply amount control valve provided in the radical supply line and configured to open and close a flow path of the radical supply line.
